(19) United States
(12) Patent Application Publication
(10) Pub. No.: US 2025/0379031 A1
(43) Pub. Date: Dec. 11, 2025

(54) TUNING DEPOSITION SELECTIVITY

(71) Applicant: Applied Materials, Inc., Santa Clara, CA (US)

(72) Inventors: Yiyang WAN, Sunnyvale, CA (US); Yunho KIM, Milpitas, CA (US); Shumao ZHANG, San Jose, CA (US); Chih-Hsun HSU, Santa Clara, CA (US); Weifeng YE, San Jose, CA (US); Jiang LU, Milpitas, CA (US)

(21) Appl. No.: 19/214,516

(22) Filed: May 21, 2025

Related U.S. Application Data
(60) Provisional application No. 63/657,017, filed on Jun. 6, 2024.

(51) Int. Cl. H01J 37/32

(52) U.S. Cl. CPC H01J 37/32146; H01J 37/3244; H01J 2237/3321; H01J 2237/3322

(57) ABSTRACT

Embodiments of the disclosure provide a method that includes delivering a pulsed radio frequency (RF) signal from a source RF generator to an electrode of a processing chamber. A plasma is formed in a processing region of the processing chamber based on the pulsed RF signal. The plasma is disposed between the electrode and a substrate. The pulsed RF signal is caused to have a duty cycle in a range of 5 to 15 percent. The pulsed RF signal is caused to have an off-time in a range of 50 to 250 microseconds. A first material is deposited on a second material of the substrate and a third material of the substrate based on the duty cycle and the off-time.

### CROSS-REFERENCE TO RELATED APPLICATIONS

This application claims the benefit of U.S. Provisional Application 63/657,017 filed on Jun. 6, 2024, which is herein incorporated by reference in its entirety.

### BACKGROUND

### Field

Embodiments described herein generally relate to a system and methods for deposition of materials. More specifically, embodiments of the present disclosure relate to an apparatus and method of tuning deposition selectivity.

### Description of the Related Art

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

An example of finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a titanium silicide layer, is required to form a reliable contact at the formed source and drain regions.

In a traditional contact junction formation process, a feature also referred to a cavity, a via, or a trench, is fabricated in the semiconductor substrate. The contact junctions allow connections between front-end-of-the-line (FEOL) semiconductor structures and back-end-of-the-line (BEOL) interconnects. Contacts with a low resistivity are desirable in semiconductor devices.

In traditional contact formation, a conformal titanium silicide (TiSi) layer is formed on a silicon or silicon germanium connection as a capping layer. However, conventional plasma enhanced-titanium (PE-Ti) deposition methods cannot meet the PE-Ti deposition on silicon (Si) to silicon nitride (SiN) selectivity requirements of next generation semiconductors. Conventional PE-Ti deposition can cause thick Ti deposits on the dielectric material (SiN) of trench sidewalls, requiring an additional wet etch procedure to remove the Ti deposit before a bottom up trench/gapfill process can be performed.

Accordingly, there is a need in the art for a method and apparatus that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the disclosure provide a method that includes delivering a pulsed radio frequency (RF) signal from a source RF generator to an electrode of a processing chamber. A plasma is formed in a processing region of the processing chamber based on the pulsed RF signal. The plasma is disposed between the electrode and a substrate. The pulsed RF signal is caused to have a duty cycle in a range of 5 to 15 percent. The pulsed RF signal is caused to have an off-time in a range of 50 to 250 microseconds. A first material is deposited on a second material of the substrate and on a third material of the substrate based on the duty cycle and the off-time.

Embodiments of the present disclosure provide an apparatus including a substrate disposed within a processing chamber. A source radio frequency (RF) generator is configured to deliver a pulsed RF signal to an electrode of the processing chamber. The pulsed RF signal has a duty cycle in a range of 5 to 15 percent and an off-time in a range of 50 to 250 microseconds. A precursor gas delivery system is configured to inject precursor gas into the processing chamber. A gas delivery system is configured to flow gas into the processing chamber. A plasma is formed within the processing based on the precursor gas and the gas. The plasma is configured to deposit a first material on a second material of the substrate and on a third material of the substrate based on the duty cycle and the off-time.

Embodiments of the present disclosure provide one or more non-transitory computer readable media storing executable instructions that, when execute by at least one processor, cause the at least one processor to perform operations including delivering a pulsed radio frequency (RF) signal to an electrode of a processing chamber. The pulsed RF signal has a duty cycle in a range of 5 to 15 percent and an off-time in a range of 50 to 250 microseconds. A plasma is formed in a processing region of the processing chamber based on the pulsed RF signal. The plasma is disposed between the electrode and a substrate. A first material is deposited on a second material of the substrate and on a third material of the substrate based on the duty cycle and the off-time.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic representation of an example substrate processing system, in accordance with certain embodiments of the present disclosure.

FIG. 2A is a schematic representation of a first material during a pulsed radio frequency (RF) signal on-time, in accordance with certain embodiments of the present disclosure.

FIG. 2B is a schematic representation of a first material during a pulsed radio frequency (RF) signal off-time, in accordance with certain embodiments of the present disclosure.

FIG. 3A is a graph illustrating a relatively high potential difference between a surface of a substrate and a plasma, in accordance with certain embodiments of the present disclosure.

FIG. 3B is a graph illustrating a relatively low potential difference between a surface of a substrate and a plasma, in accordance with certain embodiments of the present disclosure.

FIG. 4A is a schematic representation of trenches included in a surface of a substrate, in accordance with certain embodiments of the present disclosure.

FIG. 4B is a schematic representation of a first material deposited on a second material of a substrate and on a third material of the substrate, in accordance with certain embodiments of the present disclosure.

FIG. 5 is a process flow diagram illustrating a method for depositing a first material on a second material of a substrate and on a third material of the substrate, in accordance with certain embodiments of the present disclosure.

FIG. 6A illustrates an example of a radio frequency (RF) signal, according to one embodiment.

FIG. 6B illustrates an example of a pulsed radio frequency (RF) waveform, according to one embodiment.

FIG. 7 illustrates an example of portion of a radio frequency (RF) signal, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a system and methods for deposition of materials. More specifically, embodiments of the present disclosure relate to an apparatus and method of tuning deposition selectivity. In some embodiments, a substrate is disposed within a processing chamber and a precursor gas (e.g., titanium tetrachloride containing gas) is injected into the processing chamber. The substrate includes a silicon surface and a silicon-containing contact. A reducing gas (e.g., hydrogen (H₂)) is flowed into the processing chamber. In one or more embodiments, the method includes a plasma deposition process step that is performed by introducing a reducing gas (e.g., a hydrogen-containing precursor) and a metal-containing precursor and applying a radio frequency (RF) bias to an electrode within a plasma processing chamber to form, for example, a capacitively coupled plasma (CCP). In one or more embodiments, the hydrogen-containing precursor can include molecular hydrogen (H₂) and the metal-containing precursor is titanium chloride (TiCl₄). A carrier gas is flowed into the processing chamber. The carrier gas may include a noble gas, such as argon, neon, and helium, and combinations thereof. Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) and/or free radial titanium trichloride (TiCl₃*); and the hydrogen may disassociate into hydronium ions (H⁺) or hydrogen free radicals (H*). The dissociated species may then interact with the silicon surface of the silicon-containing contact, donate electrons to the silicon atoms and then each species interacts with one another and selectively form a titanium silicide layer on the top of desired surface of the substrate, such as a surface of a silicon-containing contact.

In some embodiments, the process of applying the radio frequency (RF) bias to an electrode in the plasma processing chamber includes delivering a pulsed radio frequency (RF) signal to the electrode (e.g., conductive showerhead) of the plasma processing chamber. A plasma is formed based on the pulsed RF signal, the precursor, and the reducing gas. In one or more embodiments, the pulsed RF signal has duty cycle in a range of 5 to 15 percent and an off-time in a range of 50 to 250 microseconds.

A first material (e.g., titanium) is deposited on a second material (e.g., silicon nitride) of the substrate and on a third material (e.g., silicon) of the substrate. In some embodiments, a surface of the substrate includes high aspect ratio features such as trenches having sidewalls and bottoms. The second material may be included in the sidewalls and the third material can be included in the bottoms.

In one or more embodiments, the duty cycle and the off-time of the pulsed plasma are configured to increase the selective deposition of the first material on the third material versus the deposition of the first material on the second material. The selective deposition process causes the first material to have a first thickness on the second material and the first material to have a second thickness on the third material, wherein the first thickness is less than the second thickness after performing the deposition step. This is not possible using conventional systems which are not capable of selectively depositing different amounts of a particular material on first and second portions of high aspect ratio features.

### Processing System Examples

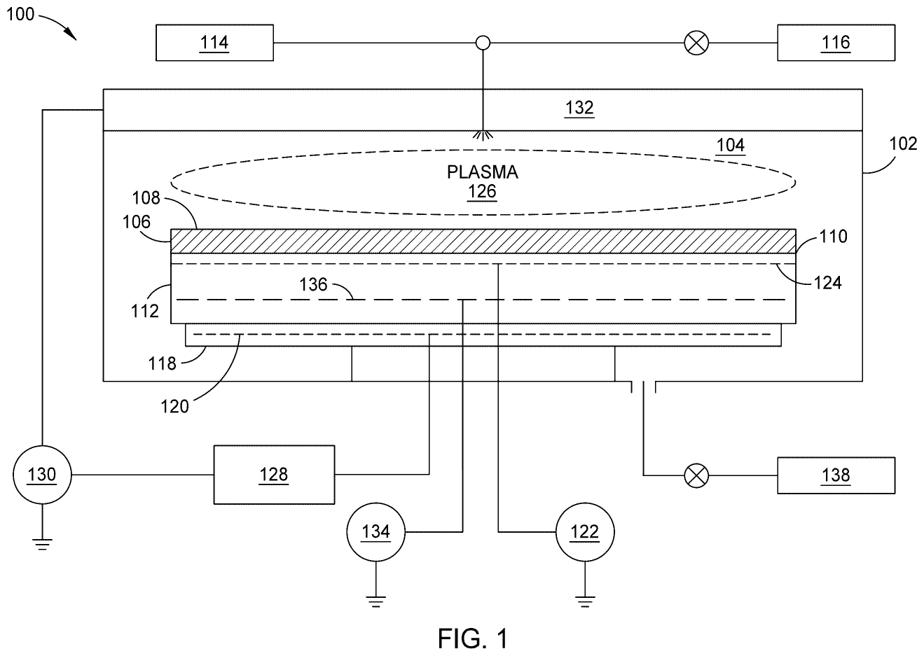

FIG. 1 is a schematic representation of an example substrate processing system 100. The substrate processing system 100 is representative of a variety of different systems such as deposition chambers (including plasma-assisted systems and non-plasma-assisted systems) and other similar processing systems or chambers. The substrate processing system 100 is illustrated to include a substrate processing chamber 102 which contains a processing region 104.

A substrate support 112 is included in the processing region 104. The substrate support 112 supports a substrate 106 during processing. The substrate 106 has a surface 108 which includes high aspect ratio features such as trenches having sidewalls and bottoms. The sidewalls and bottoms can include different materials. For example, the sidewalls may include a silicon nitride (SiN) containing material and the bottoms may include a silicon containing material (e.g., Si or SiGe).

In the illustrated example, the substrate processing system 100 includes a precursor gas delivery system 114 configured to inject gas/fluid (e.g., vapor) into the substrate processing chamber 102. In some embodiments, the precursor gas delivery system 114 is configured to inject a precursor gas such as titanium tetrachloride (TiCl₄) into the substrate processing chamber 102. In certain embodiments, precursor gas delivery system 114 is configured to inject titanium tetrachloride into the substrate processing chamber 102 at a flow rate in a range of about 5 to 100 standard cubic centimeters per minute (SCCM) such as a flow rate of about 15 SCCM. In some examples, the precursor gas delivery system 114 is configured to inject titanium tetrachloride into the substrate processing chamber 102 at a flow rate less than about 5 SCCM or greater than about 100 SCCM.

A gas delivery system 116 is coupled to the processing region 104 of the substrate processing chamber 102. The gas delivery system 116 is configured to deliver one or more gases to the processing region 104. In some embodiments, the gas delivery system 116 is configured to flow a reducing gas such as a hydrogen containing gas (e.g., H₂) into the substrate processing chamber 102. In one or more embodiments, the gas delivery system 116 is configured to flow the hydrogen containing gas into the substrate processing chamber 102 a flow rate in a range of about 30 to 6000 SCCM such as a flow rate of about 1500 SCCM. In some embodiments, the gas delivery system 116 is configured to flow a carrier gas such as argon (Ar) into the substrate processing chamber 102. In one or more embodiments, the gas delivery system 116 is configured to flow argon into the substrate processing chamber 102 at a flow rate in a range of about 1000 to 2000 SCCM such as about 1500 SCCM.

The substrate processing system 100 includes a controller 128 that is in electrical communication with a source radio frequency (RF) generator 130. In one or more embodiments, the controller 128 includes a computing device having one or more processors, support circuits, and memory. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 128 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile. The controller 128 is used to control the operation of the processing system 100.

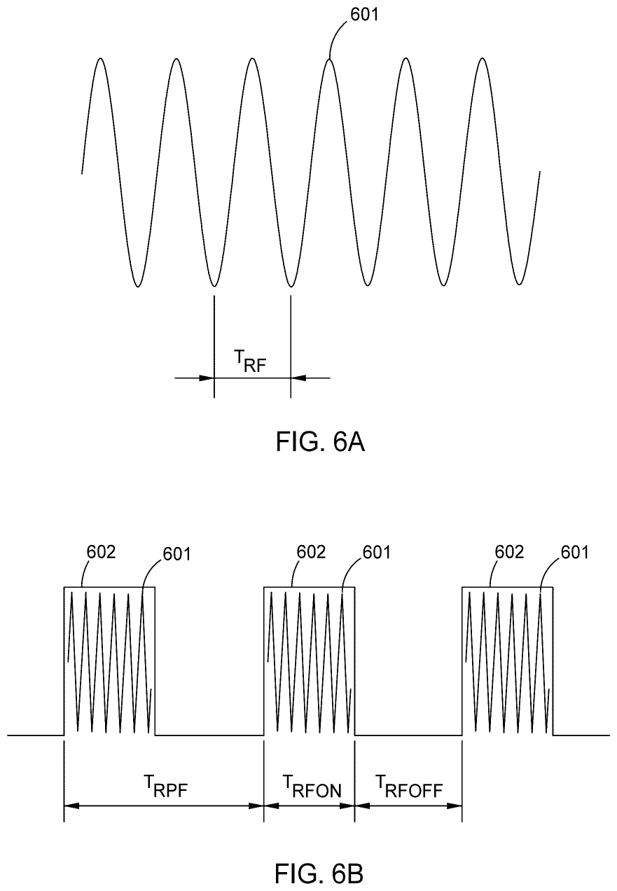

The source RF generator 130 is electrically coupled to an electrode 132 which is disposed above the substrate support 112 of the substrate processing chamber 102. In some embodiments, the RF generator 130 is configured to deliver an RF signal that includes a sinusoidal RF signal 601 as shown in FIG. 6A.

FIG. 6A illustrates a typical sinusoidal RF waveform 601 that has a frequency (i.e., 1/T_{RF}) that is provided from the RF generator 130. Typically, the one or more aspects of the plasma can be controlled by selecting a desired RF frequency and amount of RF power. The selection of a desired RF frequency is generally performed by selecting an RF generator (e.g., 350 kHz, 2 MHZ, 13.56 MHz, or 40 MHz RF generator) that is configured to provide a varying amount of RF power at one or more frequencies within a selected narrow RF frequency range. In some embodiments, the one or more processors of the controller 128 execute instructions that cause the one or more processors to deliver a pulsed RF signal to the electrode 132 from the source RF generator 130.

FIG. 6B illustrates an example of a pulsed RF waveform 602 that can be provided from the RF generator 130 during a plasma process. The formed the pulsed RF waveform 602 can have a RF pulse period T_{RFP} within an RF pulsed RF sequence, and the RF pulse period T_{RFP} will include “on” and “off” times (i.e., T_{RFON} and T_{RFOFF} respectively) within which the sinusoidal RF signal 601 is provided or not provided by the RF generator 130. In some examples, the source RF generator 130 delivers the RF signal 601 at an RF frequency in a range of about 300 to 400 KHz such as about 350 kHz. In one or more embodiments, pulses of the RF signal 601 within the pulsed RF waveform 602 have a frequency in a range of about 3 to 10 KHz such as about 5 kHz.

Delivering the pulsed RF signal to the electrode 132 generates an electric field within the substrate processing chamber 102 which is filled with the precursor gas (e.g., the titanium tetrachloride) and the reducing gas (e.g., the hydrogen). Electrons of the electric field are accelerated (e.g., by pulses of pulsed RF signal) and become high-energy electrons. Some of the high-energy electrons collide with neutral atoms/molecules of the precursor gas (e.g., the titanium tetrachloride) and the gas (e.g., the hydrogen) with sufficient energy to overcome binding energy of electrons of the neutral atoms/molecules which causes the neutral atoms/molecules to lose one or more electrons and become positively charged ions. The lost electrons are now free electrons and a plasma 126 forms as the combination of the neutral atoms/molecules of the precursor gas (e.g., the titanium tetrachloride) and the gas (e.g., the hydrogen), the positively charged ions, and the free electrons.

The plasma 126 is configured to deposit a first material (e.g., titanium from the titanium tetrachloride) on a second material (e.g., silicon nitride) of the substrate 106 and on a third material (e.g., silicon) of the substrate 106. In order to deposit different amounts of the first material on the second and third materials, the one or more processors of the controller 128 execute instructions which cause the one or more processors to cause the pulsed RF signal to have a duty cycle in a range of about 5 to 15 percent such as about 13 percent. In general, the duty cycle of a pulsed RF signal is the percentage of time that the sinusoidal RF signal is “on” (T_{RFON}) within the RF pulse period T_{RFP}. Mathematically, the duty cycle may be defined as:

$$Duty Cycle = \frac{on - time}{( on - time + off - time )} * 100 \%$$

$$where : {T}_{RFP} = ( on - time + off - time ) .$$

In some embodiments, the one or more processors of the controller 128 cause the pulsed RF signal to have an off-time in a range of about 50 to 250 microseconds such as about 175 microseconds. In one or more embodiments, the duty cycle and the off-time are configured to decrease a selective deposition of the first material on the second material or increase a selective deposition of the first material on the third material. For example, the duty cycle and the off-time may be configured to decrease an overall deposition rate of the first material on the substrate 106. In some embodiments, the duty cycle and the off-time are configured to control a potential difference between the surface 108 and the plasma 126. For example, the duty cycle and the off-time may be configured to reduce or minimize the potential difference between the surface 108 of the substrate 106 and the plasma 126. The one or more processors of the controller 128 may cause the pulsed RF signal to have an on-time in a range of about 5 to 50 microseconds (μs) such as about 25 μs. In some embodiments, the one or more processors of the controller 128 execute instructions that cause the one or more processors to cause the pulsed RF signal to have a power level in a range of about 100 to 500 W such as about 125 W.

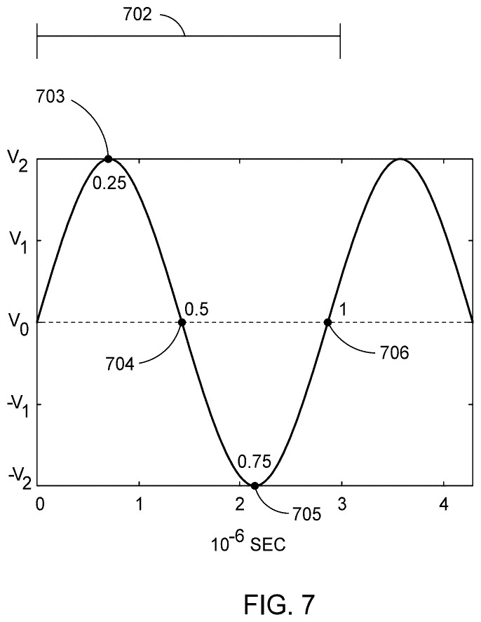

In some embodiments, the one or more processors of the controller 128 execute instructions that cause the one or more processors to apply a cut-off fraction to a RF voltage applied to the plasma 126 via the electrode 132 as shown in FIG. 7. The RF voltage has a period 702 and cut-off fractions 703-706 represent portions of the period 702 in which the RF voltage is “off” or not applied to the plasma 126. The cut-off fraction 703 is 0.25, the cut-off fraction 704 is 0.50, the cut-off fraction 705 is 0.75, and the cut-off fraction 706 is 1.00. The one or more processors of the controller 128 apply a cut-off fraction to the RF voltage to minimize a potential difference between the surface 108 of the substrate 108 and the plasma 126 which reduces deposition in some examples. For example, a cut-off fraction of 0.0 to 0.50 corresponds to the RF voltage ending at a positive voltage (e.g., voltage V₁ or V₂ in FIG. 7) which causes less ion flux and improves selectivity. It has been found that the process data exhibits an improved selectivity when the cut-off fraction is between about 0.15 and 0.30, such as about 0.25 (e.g., when the RF voltage is most positive in an RF cycle, such as voltage V₂ in FIG. 7). In some examples, it has been found that the cut-off fraction may be computed as:

$$cut - off = ( \frac{1}{pulsed RF signal frequency} ) * ( duty cycle ) * {( \frac{1}{RF signal frequency} )}^{- 1} ,$$

or, in other words,

$$cut - off = {T}_{REP} * ( duty cycle ) * 1 / {T}_{RF} ,$$

where the fractional part of the result of the “cut-off” equation determines or controls the desired processing effect (e.g., potential difference). For example, a “cut-off” equation calculation that creates a result of 8.75, based on a pulsed RF signal frequency of 10 kHz, a duty cycle of 0.25, and an RF signal frequency of 350 kHz, will have a “cut-off value” or cut-off fraction of 0.75 (or 75%) by removing the whole number portion of the calculated “cut-off” value. In another example, a result of the “cut-off” equation that is equal to 3.25 will have a “cut-off value” or cut-off fraction of 0.25 (or 25%).

In some examples, the electrode 132 is a plate for capacitively coupling power to gases present the processing region 104 above the substrate 106 supported on the substrate support 112. In other examples, the electrode 132 is one or more coils for inductively coupling power to gases present the processing region 104 above the substrate 106 supported on the substrate support 112. Although not shown, there is a matching circuit disposed between the source RF generator 130 and the electrode 132. In one or more embodiments, the substrate processing system 100 includes a bias RF generator 134 electrically connected to a bias electrode 136 disposed in the substrate support 112. In some embodiments, the bias RF generator 134 may apply an RF bias to the bias electrode 136 which can be used for tuning characteristics of the plasma 126 such as ion energy distribution, plasma density, ion flux, etc.

In some embodiments, the substrate processing system 100 includes a vacuum source 138 in communication with the processing region 104 through an exhaust port (not shown) disposed through the substrate processing chamber 102. In various embodiments, the vacuum source 138 is configured to generate vacuum pressure to control a pressure within the substrate processing chamber 102. In one or more embodiments, a pressure within the substrate processing chamber 102 may be in a range of about 3 to 10 Torr. In some embodiments, the pressure within the substrate processing chamber 102 can be less than about 3 Torr or greater than about 10 Torr. In certain embodiments, the vacuum source 138 may be configured to generate vacuum pressure to purge the titanium tetrachloride and the hydrogen from the substrate processing chamber 102. The vacuum source 138 includes one or more vacuum pumps and throttle valves that enable generation and control of vacuum pressure within the substrate processing chamber 102 and removal of process byproducts and unused processing gases.

### Tuning Deposition Selectivity Examples

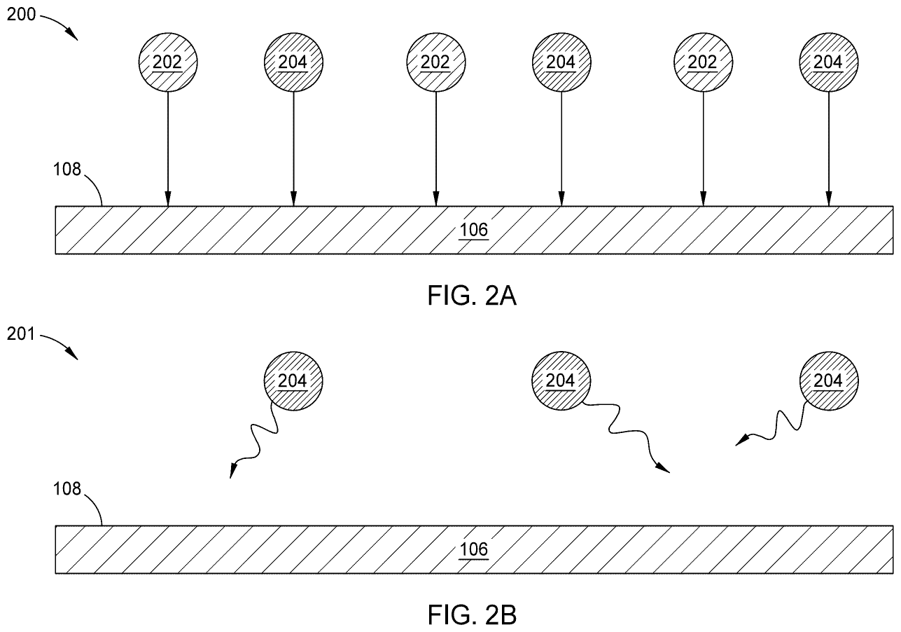

FIG. 2A is a schematic representation 200 of a first material in various different states during a pulsed radio frequency (RF) signal on-time. The representation 200 includes the substrate 106 as well as positively charged ions 202 of the first material and radicals 204 of the first material. During the pulsed RF signal on-time, the positively charged ions 202 and the radicals 204 interact with and are deposited on the surface 108 of the substrate. In some embodiments, the positively charged ions 202 have more kinetic energy and are more reactive than the radicals 204. Thus, during the RF signal on-time, the ions 202 are more likely to be deposited on the surface than the radicals 204. Notably, unlike the radicals 204 which can be preferentially, or selectively, deposited on certain materials at a greater rate than certain other materials, the ions 202 are generally deposited without preference for one material over another material.

FIG. 2B is a schematic representation 201 of a first material during a pulsed radio frequency (RF) signal off-time. The representation 201 includes the substrate 106 and the radicals 204. During the pulsed RF off-time, the plasma density is reduced and/or the plasma is extinguished, and the positively charged ions 202 are no longer generated and available for deposition on the surface 108 of the substrate 106 and the radicals 204 have insufficient energy to ballistically bombard the surface 108 of the substrate 106.

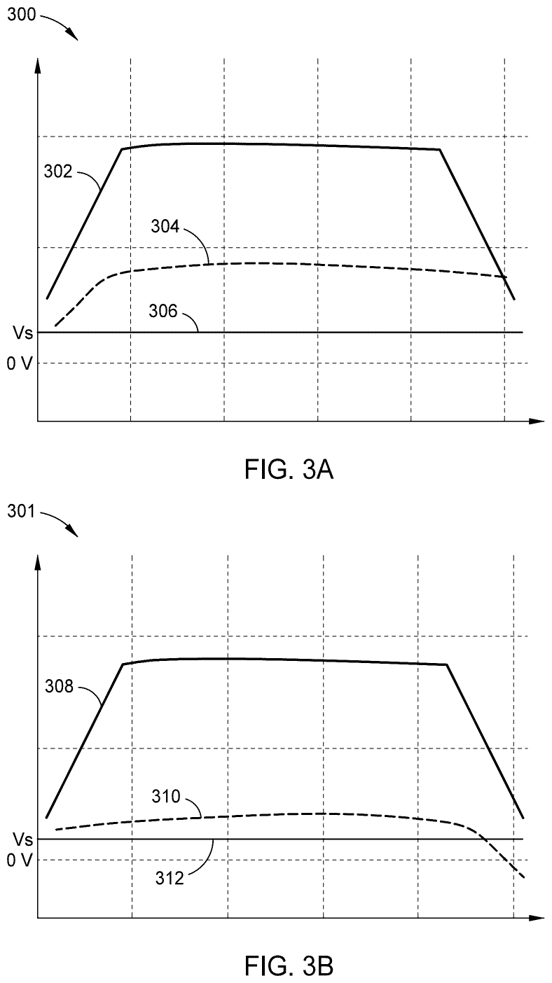

FIG. 3A is a graph 300 illustrating a relatively high potential difference between a surface 108 of a substrate 106 and a plasma 126. The graph 300 includes a plasma potential 302 of the plasma 126 during the pulsed RF on-time, a plasma potential 304 during the pulsed RF off-time, and a potential 306 of the surface 108 of the substrate 106. As shown, a difference between the plasma potential 304 and the potential 306 is relatively high (e.g., about 10 V). Because the difference between the plasma potential 304 and the potential 306 is relatively high during the plasma on-time step, a relatively large amount of the first material is deposited on the second material of the substrate 106 and on the third material of the substrate 106 without selectivity between the second and third materials.

FIG. 3B is a graph 301 illustrating a relatively low potential difference between a surface 108 of a substrate 106 and a plasma 126. The graph 301 includes a plasma potential 308 of the plasma 126 during the pulsed RF on-time, a plasma potential 310 during the pulsed RF off-time, and a potential 312 of the surface 108 of the substrate 106. A difference between the plasma potential 310 and the potential 312 is relatively low (e.g., about 1 V). Because the difference between the plasma potential 310 and the potential 312 is relatively low, a relatively small amount of the first material is deposited on the second material of the substrate 106 and a relatively large amount of the first material is deposited on the third material of the substrate 106 with selectivity between the second and third materials.

In the graph 300, the pulsed RF signal has a duty cycle of about 20 percent; however, in the graph 301, the pulsed RF signal has a duty cycle of about 30 percent. In some embodiments, the pulsed RF signal off-time is about 0.02 milliseconds after cut-off (e.g., 20 percent of a 10 KHz period), and the values illustrated in the graphs 300, 301 are average (e.g., over 350 kHz) potential values. In the graph 301, the plasma potential 310 is quickly close to 0 V due to a negative voltage applied to the electrode 132 at the time of RF cut-off. In the graph 300, at the pulsed RF signal off-time, the difference between the plasma potential 304 and the potential 306 is greater for the pulsed RF signal having the duty cycle of about 20 percent resulting in a more energetic ions to be provided in the ion flux to the substrate 106 as compared to the ion flux provided to the substrate during the deposition process shown in graph 301 with the pulsed RF signal having the duty cycle of about 30 percent.

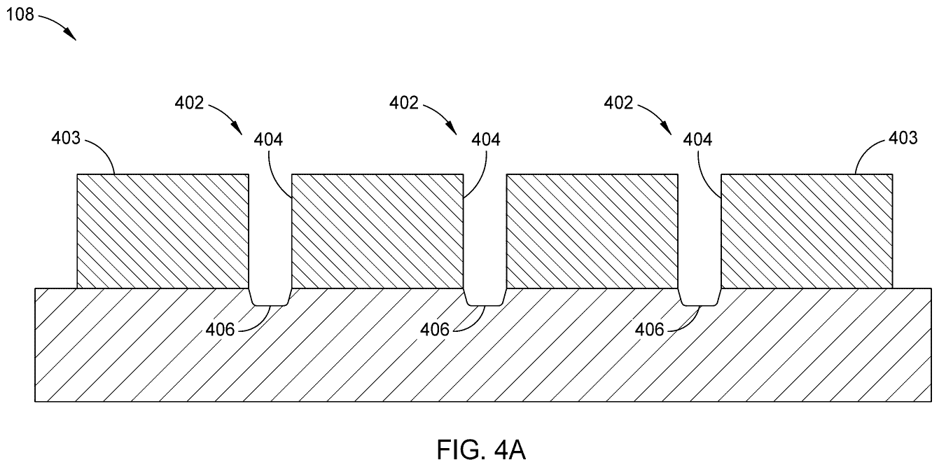

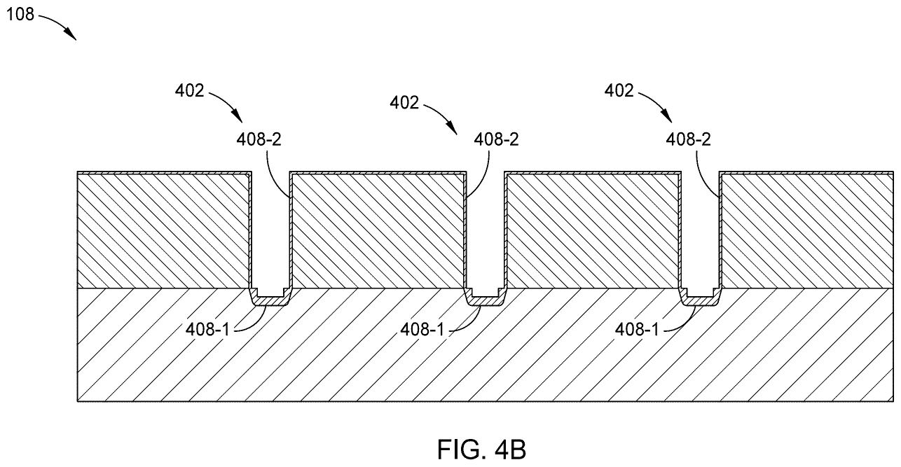

FIG. 4A is a schematic representation of trenches 402 included in a surface 108 of a substrate 106. As shown, the trenches 402 include sidewalls 404 and bottoms 406. A field region 403 separates the trenches 402. The sidewalls 404 include the second material (e.g., silicon nitride) and the bottoms 406 include the third material (e.g., silicon).

FIG. 4B is a schematic representation of a first material deposited on a second material of a substrate 106 and on a third material of the substrate 106. As shown, a first amount 408-1 of the first material (e.g., a first thickness of the first material) is deposited on the third material included in the bottoms 406. A second amount 408-2 of the first material (e.g., a second thickness of the first material) is deposited on the second material included in the field region 403 and sidewalls 404. As further shown, the first amount 408-1 is greater than the second amount 408-2 because of the duty cycle and the off-time of the pulsed RF signal. As described with respect to FIG. 3B, the reason that the first amount 408-1 is greater than the second amount 408-2 is because the duty cycle of the pulsed RF signal, the off-time of the pulsed RF signal, and the cut-off fraction for the supply voltage cause the potential difference between the plasma 126 and the surface 108 of the substrate 106 to be relatively low. The relatively low potential difference corresponds to a reduced ion energy of the ion flux to the substrate 106 which is believed to make it less likely that the deposited material will form a layer or significantly grow a layer (i.e., second amount 408-2) on the surface of the dielectric materials (e.g., SiO2 and SiN) versus form a deposited layer (i.e., first amount 408-1) on the silicon containing surfaces.

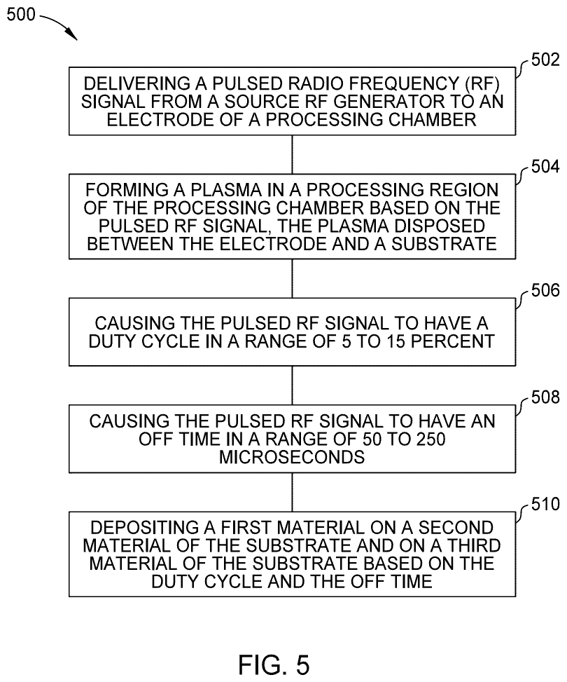

FIG. 5 is a process flow diagram illustrating a method 500 for depositing a first material on a second material of a substrate and on a third material of the substrate. At operation 502, a pulsed radio frequency (RF) signal is delivered to an electrode of a processing chamber from a source RF generator. In some embodiments, the source RF generator 130 delivers the pulsed RF signal to the electrode 132 of the substrate processing chamber 102.

At operation 504, a plasma is formed in a processing region of the processing chamber based on the pulsed RF signal, the plasma is disposed between the electrode and a substrate. In one or more embodiments, the plasma 126 is formed in the processing region 104 of the substrate processing chamber 102 between the electrode 132 and the substrate 106.

At operation 506, the pulsed RF signal is caused to have a duty cycle in a range of 5 to 15 percent. In some embodiments, the one or more processors of the controller 128 cause the pulsed RF signal to have the duty cycle in the range of 5 to 15 percent.

At operation 508, the pulsed RF signal is caused to have an off-time in a range of 50 to 250 microseconds. In one or more embodiments, the one or more processors of the controller 128 cause the pulsed RF signal to have the off-time in the range of 50 to 250 microseconds.

At operation 510, a first material is deposited on a second material of the substrate and on a third material of the substrate based on the duty cycle and the off-time. In some embodiments, the first material is deposited on the second material of the substrate 106 and on the third material of the substrate 106 based on the duty cycle and the off-time.

### ADDITIONAL CONSIDERATIONS

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or processes described with respect to one implementation may be combined with the features, components, and/or processes described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method comprising:
delivering a pulsed radio frequency (RF) signal from a source RF generator to an electrode of a processing chamber;
forming a plasma in a processing region of the processing chamber based on the pulsed RF signal, the plasma disposed between the electrode and a substrate;
causing the pulsed RF signal to have a duty cycle in a range of 5 to 15 percent;
causing the pulsed RF signal to have an off-time in a range of 50 to 250 microseconds; and
depositing a first material on a second material of the substrate and on a third material of the substrate based on the duty cycle and the off-time.

2. The method of claim 1, wherein a surface of the substrate includes trenches, the second material is included in sidewalls of the trenches, and the third material is included in bottoms of the trenches.

3. The method of claim 2, wherein the first material includes titanium, the second material includes silicon nitride, and the third material includes silicon.

4. The method of claim 2, wherein the duty cycle and the off-time are configured to decrease a selective deposition of the first material on the second material or increase a selective deposition of the first material on the third material.

5. The method of claim 1, further comprising:
injecting titanium tetrachloride into the processing chamber; and
flowing hydrogen into the processing chamber.

6. The method of claim 5, wherein the titanium tetrachloride is injected into the processing chamber at a rate in a range of 5 to 100 standard cubic centimeters per minute (SCCM).

7. The method of claim 5, wherein the hydrogen is flowed into the processing chamber at a rate in a range of 30 to 6000 SCCM.

8. The method of claim 5, wherein the plasma is formed based on the titanium tetrachloride and the hydrogen.

9. The method of claim 5, further comprising flowing argon into the processing chamber.

10. The method of claim 1, wherein the duty cycle and the off-time are configured to control a potential difference between a surface of the substrate and the plasma.

11. The method of claim 10, wherein the duty cycle and the off-time are configured to reduce the potential difference.

12. An apparatus, comprising:
a substrate disposed within a processing chamber;
a source radio frequency (RF) generator configured to deliver a pulsed RF signal to an electrode of the processing chamber, the pulsed RF signal having a duty cycle in a range of 5 to 15 percent and an off-time in a range of 50 to 250 microseconds;
a precursor gas delivery system configured to inject precursor gas into the processing chamber;
a gas delivery system configured to flow gas into the processing chamber; and
a plasma formed within the processing chamber based on the precursor gas and the gas, the plasma configured to deposit a first material on a second material of the substrate and on a third material of the substrate based on the duty cycle and the off-time.

13. The apparatus of claim 12, wherein the precursor gas includes titanium tetrachloride and the gas includes hydrogen.

14. The apparatus of claim 12, wherein the duty cycle and the off-time are configured to decrease a selective deposition of the first material on the second material or increase a selective deposition of the first material on the third material.

15. The apparatus of claim 12, wherein a surface of the substrate includes trenches, the second material is included in sidewalls of the trenches, and the third material is included in bottoms of the trenches.

16. The apparatus of claim 12, wherein the precursor gas is injected into the processing chamber at a rate in a range of 5 to 100 standard cubic centimeters per minute (SCCM).

17. The apparatus of claim 12, wherein the gas is flowed into the processing chamber at a rate in a range of 30 to 6000 SCCM.

18. The apparatus of claim 12, wherein the duty cycle and the off-time are configured to control a potential difference between a surface of the substrate and the plasma.

19. One or more non-transitory computer readable media storing executable instructions that, when execute by at least one processor, cause the at least one processor to perform operations comprising:
delivering a pulsed radio frequency (RF) signal to an electrode of a processing chamber, the pulsed RF signal having a duty cycle in a range of 5 to 15 percent and an off-time in a range of 50 to 250 microseconds;
forming a plasma in a processing region of the processing chamber based on the pulsed RF signal, the plasma disposed between the electrode and a substrate; and
depositing a first material on a second material of the substrate and on a third material of the substrate based on the duty cycle and the off-time.

20. The one or more non-transitory computer readable media of claim 19, wherein the duty cycle and the off-time are configured to decrease a selective deposition of the first material on the second material or increase a selective deposition of the first material on the third material.
